(19) United States
(12) Patent Application Publication
(10) Pub. No.: US 2025/0056789 A1
(43) Pub. Date: Feb. 13, 2025

(54) SEMICONDUCTOR MEMORY DEVICE

(71) Applicant: SAMSUNG ELECTRONICS CO., LTD., Suwon-si (KR)

(72) Inventors: Dae-Jin Nam, Suwon-si (KR); Sung-Hwan Jang, Suwon-si (KR); Won Hee Choi, Suwon-si (KR); Sung Uk Jang, Suwon-si (KR)

(21) Appl. No.: 18/620,333

(22) Filed: Mar. 28, 2024

(30) Foreign Application Priority Data
Aug. 9, 2023 (KR) 10-2023-0104235

(51) Int. Cl. H10B 12/00

(52) U.S. Cl. CPC H10B 12/30; H10B 12/05

(57) ABSTRACT

The present disclosure relates to semiconductor memory devices. An example semiconductor memory device comprises a substrate, a structure including word lines and interlayer insulating films alternately stacked on the substrate, a channel region disposed between two adjacent word lines in a vertical direction, a first source/drain region disposed on a first side of the channel region, a second source/drain region disposed on a second side of the channel region, a bit line which extends in the vertical direction on the substrate and is connected to the first source/drain region, a capping insulating film disposed between the bit line and the word lines, and a data storage connected to the second source/drain region. At least a part of the first source/drain region protrudes from a sidewall of the capping insulating film toward the bit line.

### CROSS-REFERENCE TO RELATED APPLICATION

This application claims priority from Korean Patent Application No. 10-2023-0104235 filed on Aug. 9, 2023 in the Korean Intellectual Property Office, and all the benefits accruing therefrom under 35 U.S.C. 119, the contents of which are herein incorporated by reference in their entirety.

### BACKGROUND

In the case of a two-dimensional or planar semiconductor element of the related art, the degree of integration is mainly determined by an area occupied by unit memory cells, and is therefore greatly affected by the level of fine pattern forming technology. However, since ultra-expensive apparatuses are required to miniaturize the pattern, the degree of integration of the two-dimensional semiconductor element is increasing, but is still limited. Accordingly, three-dimensional semiconductor memory elements including memory cells arranged three-dimensionally have been proposed.

### SUMMARY

The present disclosure relates to semiconductor memory devices, including a semiconductor memory device having improved performance and reliability.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

In general, according to some aspects, a semiconductor memory device comprises a substrate, a stacked structure including word lines and interlayer insulating films, wherein the word lines and the interlayer insulating films are alternately stacked on the substrate, a channel region disposed between the word lines adjacent to each other in a vertical direction, a first source/drain region disposed on one side of the channel region, a second source/drain region disposed on the other side of the channel region, a bit line which extends in the vertical direction on the substrate, and is connected to the first source/drain region, a capping insulating film disposed between the bit line and the word lines, and a data storage element connected to the second source/drain region, wherein at least a part of the first source/drain region protrudes from a sidewall of the capping insulating film toward the bit line.

In general, according to some aspects, a semiconductor memory device comprises a substrate, a stacked structure including word lines and interlayer insulating films, wherein the word lines and the interlayer insulating films are alternately stacked on the substrate, a channel region disposed between word lines adjacent to each other in a vertical direction, a bit line which extends in the vertical direction on the substrate, capping insulating films disposed between the bit line and the word lines, a first source/drain region which is disposed between the bit line and the channel region and between the capping insulating films adjacent to each other in the vertical direction, and at least partially overlaps the bit line in the vertical direction, a second source/drain region opposite to the first source/drain region with the channel region interposed therebetween, and a data storage element connected to the second source/drain region, wherein the first source/drain region includes a first region overlapping the bit line in the vertical direction, and a second region between the first region and the channel region, and wherein a width of the first region in the vertical direction increases and then decreases, as it goes away from the channel region.

In general, according to some aspects, a semiconductor memory device comprises a substrate, a stacked structure including word lines and interlayer insulating films, wherein the word lines and the interlayer insulating films are alternately stacked on the substrate, a channel region disposed between the word lines adjacent to each other in a vertical direction, a first source/drain region disposed on one side of the channel region, a second source/drain region disposed on the other side of the channel region, a bit line which extends in the vertical direction on the substrate and is connected to the first source/drain region, a silicide film interposed between the first source/drain region and the bit line, capping insulating films disposed between the bit line and the word lines, and a data storage element connected to the second source/drain region, wherein the data storage element includes a storage electrode connected to the second source/drain region, a plate electrode on the storage electrode, and a capacitor dielectric film between the storage electrode and the plate electrode, wherein the first source/drain region includes a first region that protrudes from sidewalls of the capping insulating films and overlaps the bit line in the vertical direction, and a second region between the first region and the channel region, wherein a sidewall of the first source/drain region include first and second extending parts that are opposite to each other, wherein a distance in the vertical direction from the first extending part to the second extending part increases and then decreases, as it goes away from the channel region, and wherein at a boundary between the first source/drain region and the channel region, the first source/drain region or the channel region includes oxygen (O), fluorine (F), chlorine (Cl) or bromine (Br).

### BRIEF DESCRIPTION OF THE DRAWINGS

The above and other aspects and features of the present disclosure will become more apparent by describing in detail example implementations thereof with reference to the attached drawings, in which:

FIG. 1 is an example circuit diagram showing a cell array of a semiconductor memory device.

FIG. 2 is an example perspective view for explaining a semiconductor memory device.

FIG. 3 is an example plan view for explaining the semiconductor memory device.

FIG. 4 is an example cross-sectional view taken along line A-A′ of FIG. 2.

FIG. 5 is an example cross-sectional view taken along line B-B′ of FIG. 3.

FIG. 6 is an example cross-sectional view taken along line C-C′ of FIG. 3.

FIG. 7 is an example enlarged view of the region P of FIG. 4.

FIGS. 8 to 13 are example diagrams of the semiconductor memory device.

FIGS. 14 to 27 are example intermediate diagrams for explaining the method for fabricating a semiconductor memory device.

### DETAILED DESCRIPTION

Although terms such as first and second are used to describe various elements or components in the present specification, these elements or components are not limited by these terms. These terms are only used to distinguish a single element or component from other elements or components. Therefore, a first element or component referred to below may be a second element or component within the technical idea of the present disclosure.

Hereinafter, in order to describe the present disclosure more specifically, the present disclosure will be described in more detail with reference to the accompanying drawings according to some implementations of the present disclosure.

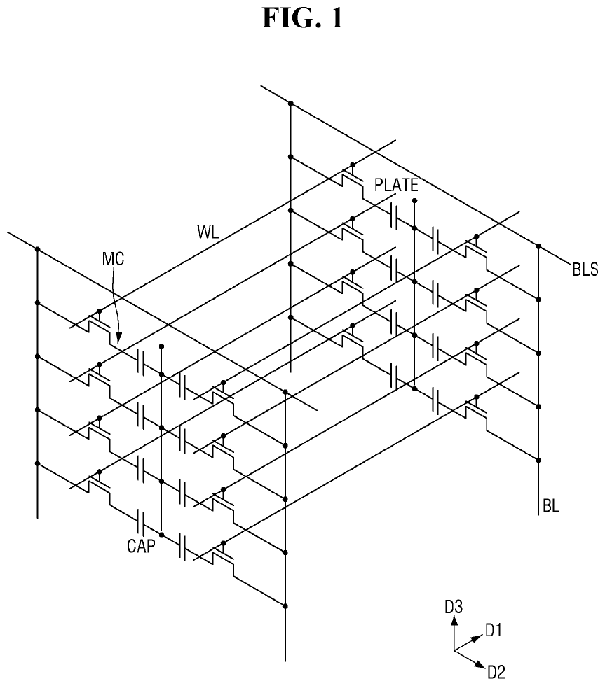

FIG. 1 is an example circuit diagram showing a cell array of a semiconductor memory device.

Referring to FIG. 1, the semiconductor memory device includes a plurality of memory cells MC arranged along a second direction D2 and a third direction D3. Each memory cell MC includes a memory cell transistor and a data storage element CAP which are disposed along the second direction D2 and connected to each other.

Bit lines BL may be conductive patterns (e.g., metallic conductive lines) extending in a perpendicular direction (i.e., the third direction D3) from a substrate. The bit lines BL may be arranged in the second direction D2. The bit lines BL adjacent to each other may be spaced apart from each other in the second direction D2.

In some implementations, some of the plurality of bit lines BL may be connected together by a bit line strapping line (BLS). For example, the bit line strapping line BLS may connect the bit lines BL arranged along the second direction D2 among the plurality of bit lines BL to each other.

Word lines WL may be conductive patterns (e.g., metallic conductive lines) stacked on the substrate in the third direction D3. Each word line WL may extend in the first direction D1. The word lines BL adjacent to each other may be spaced apart from each other in the third direction D3.

The data storage element CAP may be commonly connected to plate electrodes PLATE extending in the first direction D1 and the third direction D3. In some implementations, the plate electrodes PLATE arranged along the first direction D1 may be integrated.

The data storage elements CAP and the memory cell transistors arranged along the second direction D2 may be symmetrically arranged on the basis of the plane extending in the first direction D1 and the third direction D3 on which the plate electrodes PLATE are disposed.

A gate of the memory cell transistor may be connected to the word line WL, and a first source/drain of the memory cell transistor may be connected to the bit line BL. A second source/drain of the memory cell transistor may be connected to the data storage element CAP. For example, the data storage element CAP may be a capacitor. The second source/drain of the memory cell transistor may be connected to the storage electrode of the capacitor. In the implementations illustrated herein, the phrase source/drain may be understood to mean a source terminal or a drain terminal of a transistor.

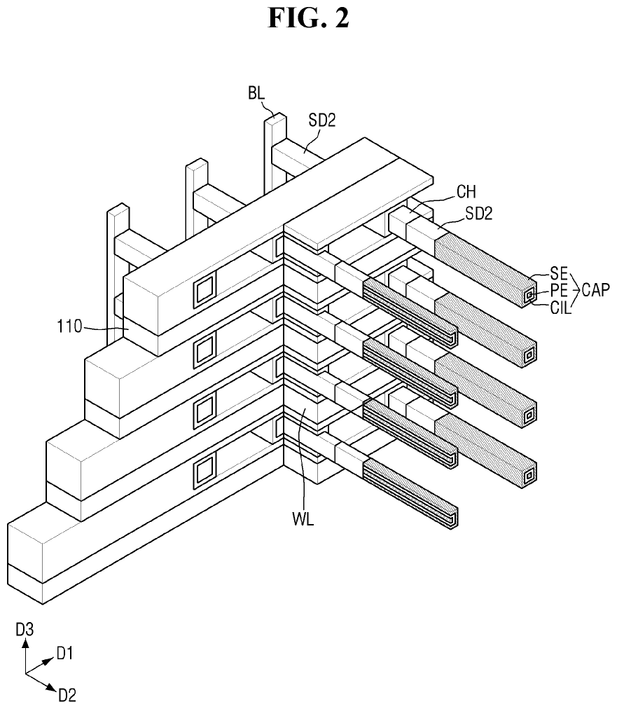

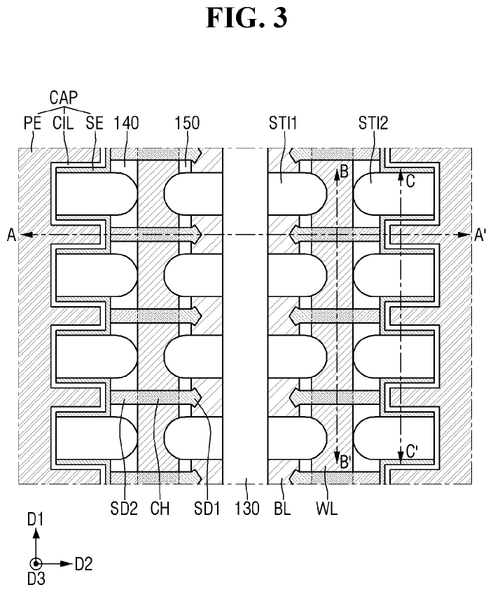

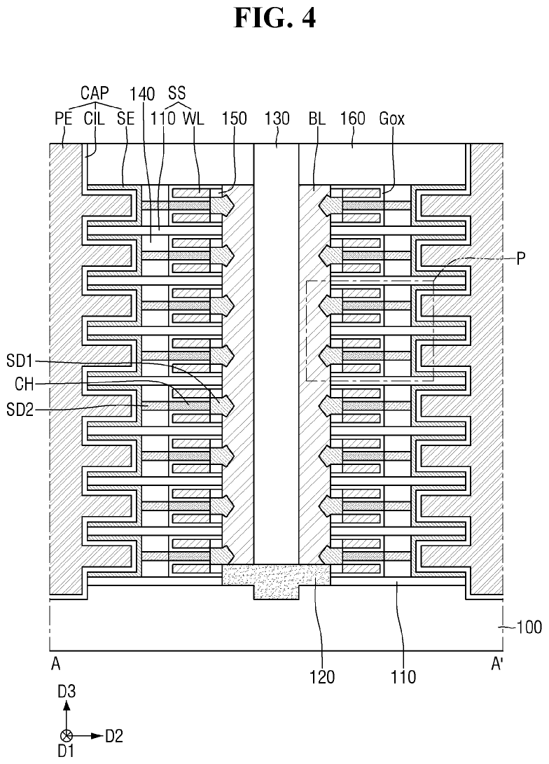

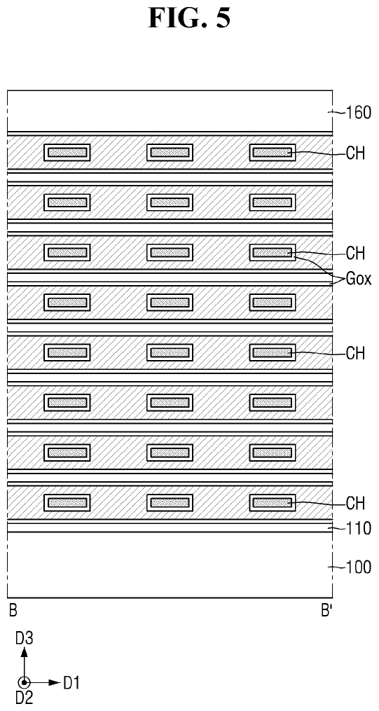

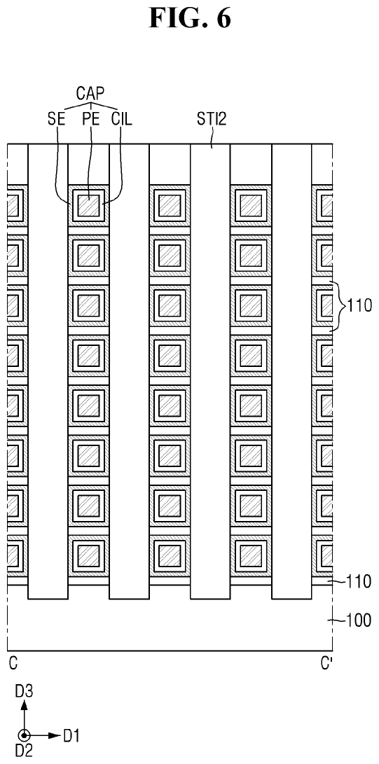

FIG. 2 is an example perspective view for explaining a semiconductor memory device. FIG. 3 is an example plan view for explaining the semiconductor memory device. FIG. 4 is an example cross-sectional view taken along line A-A′ of FIG. 2. FIG. 5 is an example cross-sectional view taken along line B-B′ of FIG. 3. FIG. 6 is an example cross-sectional view taken along line C-C′ of FIG. 3.

Referring to FIGS. 2 to 6, the semiconductor memory device includes a substrate 100, a stacked structure SS, a channel region CH, first and second source/drain regions SD1 and SD2, a bit line BL, and a data storage element CAP.

An upper side of the substrate 100 may be disposed in a plane along which the first direction D1 and the second direction D2 extend. The upper side of the substrate 100 may be orthogonal to the third direction D3. In this specification, the first direction D1, the second direction D2, and the third direction D3 may intersect each other. The first direction D1, the second direction D2 and the third direction D3 may be substantially perpendicular to each other.

The substrate 100 may be bulk silicon or silicon-on-insulator (SOI). In contrast, the substrate 100 may be a silicon substrate, or may include other materials, for example, but not limited to, silicon germanium, silicon germanium on insulator (SGOI), indium antimonide, lead telluride, indium arsenide, indium phosphide, gallium arsenide or gallium antimonide. In the following description, the substrate 100 will be described as a substrate including silicon.

The stacked structure SS may be disposed on the substrate 100. The stacked structure SS may include a plurality of interlayer insulating films 110 and a plurality of word lines WL. The plurality of interlayer insulating films 110 and the plurality of word lines WL may be alternately and repeatedly stacked in the third direction D3. For example, two word lines WL may be disposed between the interlayer insulating films 110 adjacent in the third direction D3.

Each of the word lines WL may include a line part extending in the first direction D1 parallel to the upper side of the substrate 100, and a gate electrode part protruding in the second direction D2. Here, the line part may be provided between a first isolation insulating pattern STI1 and a second isolation insulating pattern STI2 that are spaced apart from each other. That is, the line part may overlap the first isolation insulating pattern STI1 and the second isolation insulating pattern STI2 in the second direction D2. The protruding part may not overlap the first isolation insulating pattern STI1 and the second isolating insulating pattern STI2 in the second direction D2. From a planar viewpoint, the pair of word lines WL may be symmetrical to each other on the basis of a vertical insulating pattern 130, which will be described below.

The word lines WL may include a conductive material. As an example, the word lines WL may include, but not limited to, at least one of a doped semiconductor material (doped silicon, doped silicon-germanium, doped germanium, etc.), conductive metal nitride (titanium nitride, tantalum nitride, etc.), a metal (tungsten, titanium, tantalum, etc.), and metal-semiconductor compounds (tungsten silicide, cobalt silicide, titanium silicide, etc.).

The interlayer insulating films 110 may be provided between the word lines WL adjacent in the third direction D3. The interlayer insulating films 110 may electrically isolate the word lines WL. Some of the interlayer insulating films 110 may electrically isolate the data storage elements CAP. At least some of the interlayer insulating films 110 may overlap the data storage element CAP in the third direction D3. Some of the interlayer insulating films 110 may be in contact with the storage electrode SE of the data storage element CAP. Some others of the interlayer insulating films 110 may be in contact with a capacitor dielectric film CIL of the data storage element CAP. Some others of the interlayer insulating films 110 may be in contact with the second source/drain region SD2, a gate insulating film Gox, and the bit line BL.

The interlayer insulating films 110 may include an insulating material. The interlayer insulating films 110 may include, for example, at least one of a silicon oxide film, a silicon nitride film, a silicon oxynitride film, a carbon-containing silicon oxide film, a carbon-containing silicon nitride film, and a carbon-containing silicon oxynitride film. As an example, the interlayer insulating film 110 may include a silicon oxide film.

The channel regions CH may be stacked in the third direction D3. The channel regions CH may be provided between the word lines WL adjacent in the third direction D3. For example, assuming that three word lines WL are provided, the channel region CH may be provided between the first and second word lines, and the interlayer insulating film 110 may be formed between the second and third word lines. However, the technical idea of the present disclosure is not limited thereto.

The channel regions CH may be spaced apart from each other in the first direction D1 and the third direction D3. The channel regions CH may extend in the second direction D2. That is, the channel regions CH may be arranged three-dimensionally on the substrate 100. The channel regions CH may include at least one of silicon and germanium. As an example, the channel regions CH may include monocrystalline silicon.

Each of the channel regions CH may have a bar shape having a long axis in the second direction D2. The channel regions CH may penetrate the word lines WL in the second direction D2. Each word line WL may have a structure (that is, a gate-all-around structure) that completely surrounds the channel regions CH. The gate insulating film Gox may be interposed between the channel regions CH and the word lines WL. The gate insulating film Gox may be in contact with each of the capping insulating film 150 to be described below, and a spacer insulating film 140 to be described below. The gate insulating film Gox may be in contact with the interlayer insulating film 110.

The gate insulating film Gox may include at least one of a high dielectric constant insulating film, a silicon oxide film, a silicon nitride film, and a silicon oxynitride film. As an example, the high dielectric constant insulating film may include at least one of hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide and lead zinc niobate.

The first source/drain region SD1 may be disposed on one side of the channel region CH. The second source/drain region SD2 may be disposed on the other side of the channel region CH. The first source/drain region SD1 and the second source/drain region SD2 may be symmetrical with each other with the channel region CH interposed therebetween. The first source/drain region SD1 and the second source/drain region SD2 may each include impurity-doped silicon. For example, although the first source/drain region SD1 and the second source/drain region SD2 may each include SiP or SiAs, the technical idea of the present disclosure is not limited thereto.

In some implementations, the concentration of impurities included in the first source/drain region SD1 may be greater than the concentration of impurities included in the second source/drain region SD2. This may be because the first source/drain region SD1 is formed using a selective epitaxial growth (SEG) process, and the second source/drain region SD2 is formed using an ion doping process.

The first source/drain region SD1 may be connected to the bit line BL. The second source/drain region SD2 may be connected to the data storage element CAP. For example, the second source/drain region SD2 may be connected to the storage electrode SE of the data storage element CAP.

The capping insulating films 150 may be provided between the bit lines BL and the word lines WL. The capping insulating films 150 may be provided between the first source/drain region SD1 and the interlayer insulating film 110. The capping insulating films 150 may electrically separate the bit lines BL and the word lines WL. The capping insulating films 150 may surround the first source/drain region SD1. The capping insulating films 150 may be in direct contact with the word lines WL. Although the capping insulating films 150 may be in direct contact with the first source/drain region SD1, the technical idea of the present disclosure is not limited thereto.

The capping insulating films 150 may include, for example, at least one of a silicon oxide film, a silicon nitride film, a silicon oxynitride film, a carbon-containing silicon oxide film, a carbon-containing silicon nitride film, and a carbon-containing silicon oxynitride film. As an example, the capping insulating film 150 may be formed of a silicon nitride film.

The spacer insulating film 140 may be provided between the word lines WL and the data storage elements CAP. The spacer insulating film 140 may be provided between the second source/drain region SD2 and the interlayer insulating film 110. The spacer insulating film 140 may be spaced apart from the word lines WL with the gate insulating film Gox therebetween. In some implementations, the spacer insulating film 140 may be formed of multiple films. For example, when the spacer insulating film 140 is formed of multiple films, the spacer insulating film 140 may include a liner film and a filling film. The liner film may surround the second source/drain region SD2 and the interlayer insulating film 110. The filling film may fill the inside of a trench defined by the liner film, the gate insulating film Gox, and the storage electrode SE.

The spacer insulating film 140 may include, for example, at least one of a silicon oxide film, a silicon nitride film, a silicon oxynitride film, a carbon-containing silicon oxide film, a carbon-containing silicon nitride film, and a carbon-containing silicon oxynitride film.

The semiconductor memory device may further include a first isolation insulating pattern STI1, a second isolation insulating pattern STI2, a lower protective pattern 120, a vertical insulating pattern 130, and an upper insulating film 160.

The lower protective pattern 120 may be provided on the substrate 100. The lower protective pattern 120 may be provided between the substrate 100 and the bit line BL. The lower protective pattern 120 may be provided between the word lines WL nearest to the substrate 100. The lower protective pattern 120 may be formed of the same material as the capping insulating film 150, but the technical idea of the present disclosure is not limited thereto.

The vertical insulating pattern 130 may be disposed on the lower protective pattern 120. The vertical insulating pattern 130 may be provided between the bit lines BL. The vertical insulating pattern 130 may extend on the lower protective pattern 120 in the third direction D3. The vertical insulating pattern 130 may cover side walls of the bit line BL and side walls of the first isolation insulating patterns STI1. The vertical insulating pattern 130 may be formed of at least one of insulating materials, silicon oxide, and silicon oxynitride formed, using a spin-on-glass (SOG) technique.

The upper insulating film 160 may be formed on the stacked structure SS. The upper insulating film 160 may be provided between the plate electrode PE and the vertical insulating pattern 130. The upper insulating film 160 may be formed of a silicon oxide film, but the technical idea of the present disclosure is not limited thereto.

The first isolation insulating pattern STI1 may be provided between the word lines WL and the vertical insulating patterns 130, and between the bit lines BL. The second isolation insulating pattern STI2 may be provided between the word line WL and the data storage element CAP, and between the storage electrodes SE. Each of the first isolation insulating pattern STI1 and the second isolation insulating pattern STI2 may be formed of an insulating material. As an example, the first isolation insulating pattern STI1 and the second isolation insulating pattern STI2 may each be formed of a silicon oxide film.

The data storage element CAP may be connected to the second source/drain region SD2. In some implementations, the data storage element CAP may be a capacitor. The data storage element CAP may include a storage electrode SE, a plate electrode PE, and a capacitor dielectric film CIL. The data storage elements CAP may share the capacitor dielectric film CIL and the plate electrode PE. That is, a plurality of storage electrodes SE connected to each of the second source/drain regions SD2 are provided, and one capacitor dielectric film CIL may cover the surface of each storage electrode SE. One plate electrode PE may cover the capacitor dielectric film CIL. The plate electrode PE may be the same as the plate electrode PLATE of FIG. 1. That is, each data storage element CAP may be defined by the storage electrode SE.

The storage electrode SE may have a cylindrical shape with an empty inside in which a first portion facing the second source/drain region SD2 is closed, and a second portion opposite to the first portion is opened. In other words, the storage electrode SE may have a U shape rotated by 90 degrees. The storage electrode SE may be electrically connected to the second source/drain region SD2. The storage electrode SE may, for example, directly abut on the second source/drain region SD2.

The storage electrode SE and the plate electrode PE may each include, for example, but not limited to, doped semiconductor materials, conductive metal nitride (e.g., titanium nitride, tantalum nitride, niobium nitride or tungsten nitride, etc.), metal (e.g., ruthenium, iridium, titanium, niobium, tungsten, cobalt, molybdenum or tantalum, etc.), and conductive metal oxide (e.g., iridium oxide or niobium oxide, etc.). As an example, the storage electrode SE may include conductive metal nitride, metal, and conductive metal oxide. The conductive metal nitride, the metal and the conductive metal oxide may be included in the metallic conductive film.

The capacitor dielectric film CIL may include, for example, high dielectric constant materials (e.g., hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, lead zinc niobate or combinations thereof). In some implementations, the capacitor dielectric film CIL may include a stacked film structure in which zirconium oxide, aluminum oxide, and zirconium oxide are sequentially stacked. In some implementations, the capacitor dielectric film CIL may include hafnium (Hf).

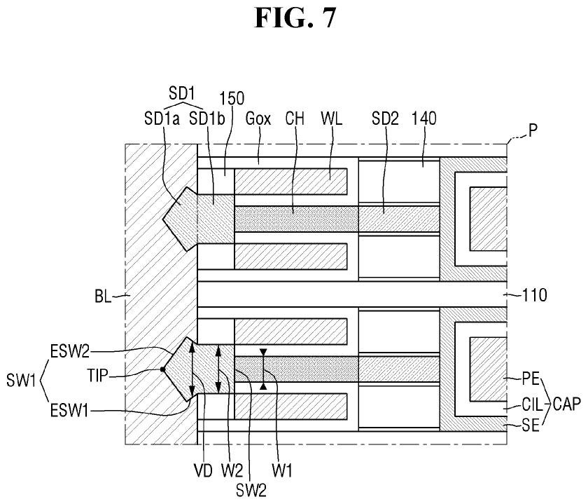

Hereinafter, in some implementations, the first source/drain region SD1, the bit line BL, and the capping insulating film 150 will be described in more detail. FIG. 7 is an example enlarged view of the region P of FIG. 4.

Referring to FIG. 7, at least a part of the first source/drain region SD1 is disposed inside the bit line BL. The first source/drain region SD1 protrudes from side walls of the capping insulating film 150 toward the bit line BL.

For example, the first source/drain region SD1 may include a first region SD1a and a second region SD1b.

The first region SD1a of the first source/drain region SD1 may be provided inside the bit line BL. The first region SD1a of the first source/drain region SD1 may be a portion that protrudes from the side wall of the capping insulating film 150 toward the bit line BL. The first region SD1a of the first source/drain region SD1 may overlap the bit line BL in the third direction D3. At least a part of the first region SD1a of the first source/drain region SD1 may overlap the capping insulating film 150 in the second direction D2. At least a part of the first region SD1a of the first source/drain region SD1 may overlap the word line WL in the second direction D2.

The second region SD1b of the first source/drain region SD1 may be provided between the first region SD1a and the channel region CH. The second region SD1b of the first source/drain region SD1 does not overlap the bit line BL in the third direction D3. That is, an imaginary boundary line between the first region SD1a of the first source/drain region SD1 and the second region SD1b of the first source/drain region SD1 may be coplanar with a boundary line between the capping insulating film 150 and the bit line BL.

In some implementations, the first source/drain region SD1 may include a first side wall SW1 adjacent to the bit line BL, and a second side wall SW2 opposite to the bit line BL.

The first side wall SW1 adjacent to the bit line BL may be in contact with the bit line BL. However, the technical idea of the present disclosure is not limited thereto. The first side wall SW1 may not be in direct contact with the bit line BL. The second side wall SW2 opposite to the bit line BL may be in contact with the channel region CH. That is, the second side wall SW2 may be a boundary between the first source/drain region SD1 and the channel region CH.

In some implementations, the first side wall SW1 may include a first extending part ESW1 and a second extending part ESW2. The first extending part ESW1 and the second extending part ESW2 may be opposite to each other. The first extending part ESW1 may face the substrate 100, and the second extending part ESW2 may face the upper insulating film 160.

The first extending part ESW1 may include a tip part. For example, the first extending part ESW1 may include a first portion that is in contact with the second extending part ESW2, and a second portion that is in contact with the second region SD1b. The first extending part ESW1 may include a tip part at a portion in which the first portion and the second part are in contact with each other.

Similarly, the second extending part ESW2 may include a tip part. For example, the second extending part ESW2 may include a third portion that is in contact with the first extending part ESW1, and a fourth portion that is in contact with the second region SD1b. The second extending part ESW2 may include a tip part at the portion in which the third portion and the fourth portion are in contact with each other.

In some implementations, the first side wall SW1 may include a tip part TIP. The tip part TIP may be formed at a portion in which the first extending part ESW1 and the second extending part ESW2 are in contact with each other. However, the technical idea of the present disclosure is not limited thereto.

In some implementations, a vertical distance VD in the third direction D3 between the first extending part ESW1 and the second extending part ESW2 may increase and then decrease, as it goes away from the channel region CH. This may be because the first source/drain region SD1 is formed, using the SEG process. The vertical distance VD may be a width of the first region SD1a of the first source/drain region SD1 in the third direction D3.

In some implementations, the channel region CH may have a first width W1 in the third direction D3 at the boundary between the channel region CH and the first source/drain regions SD1. At the boundary between the channel region CH and the first source/drain region SD1, the first source/drain region SD1 may have a second width W2 in the third direction D3. The first width W1 may be smaller than the second width W2. This may be because a part of the gate insulating film Gox that is in contact with the capping insulating film 150 is removed in the process of forming the first source/drain region SD1. The size of the second width W2 may be increased to the extent of removal of a part of the gate insulating film Gox. However, the technical idea of the present disclosure is not limited thereto.

In some implementations, a part of the second region SD1b of the first source/drain region SD1 may be in contact with the capping insulating film 150. As described above, a part of the gate insulating film Gox may be removed in the process of forming the first source/drain region SD1. The second region SD1b of the first source/drain region SD1 may be formed in the space from which the gate insulating film Gox is removed. Accordingly, at least a part of the second region SD1b of the first source/drain region SD1 may be in contact with the capping insulating film 150. At least a part of the second region SD1b of the first source/drain region SD1 may overlap the gate insulating film Gox in the second direction D2. On the other hand, the second region SD1b of the first source/drain region SD1 may not overlap the gate insulating film Gox in the third direction D3.

In some implementations, at the boundary between the first source/drain region SD1 and the channel region CH, the first source/drain region SD1 or the channel region CH may include oxygen (O), fluorine (F), chlorine (Cl) or bromine (Br).

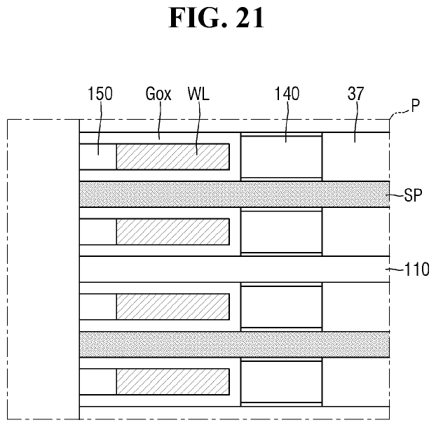

A part of the semiconductor pattern (e.g., SP of FIG. 21) may be etched in the process of forming the first source/drain region SD1. An etchant used in the process of etching a part of the semiconductor pattern (e.g., SP of FIG. 21) may include fluorine (F), chlorine (Cl) or bromine (Br). Therefore, at the boundary between the first source/drain region SD1 and the channel region CH, the first source/drain region SD1 or the channel region CH may include fluorine (F), chlorine (Cl) or bromine (Br).

Also, the surface of the channel region CH may be exposed by partially etching the semiconductor pattern (e.g., SP of FIG. 21). Therefore, the first source/drain region SD1 or the channel region CH may include oxygen (O) at the boundary between the first source/drain region SD1 and the channel region CH.

In some implementations, the structure of a crystal grain of the first source/drain region SD1 and the structure of a crystal grain of the channel region CH may be different from each other. The first source/drain region SD1 may include structural defects. This may be because the first source/drain region SD1 is formed, using the SEG process.

As such, the first source/drain region SD1 may be formed by etching a part of the semiconductor pattern and using the SEG process. Therefore, a source/drain region with relatively high impurity concentration may be formed. Also, since a part of the first source/drain region SD1 is disposed inside the bit line BL, the area of the contact portion between the first source/drain region SD1 and the bit line BL may increase. Accordingly, a semiconductor memory device with improved reliability may be fabricated.

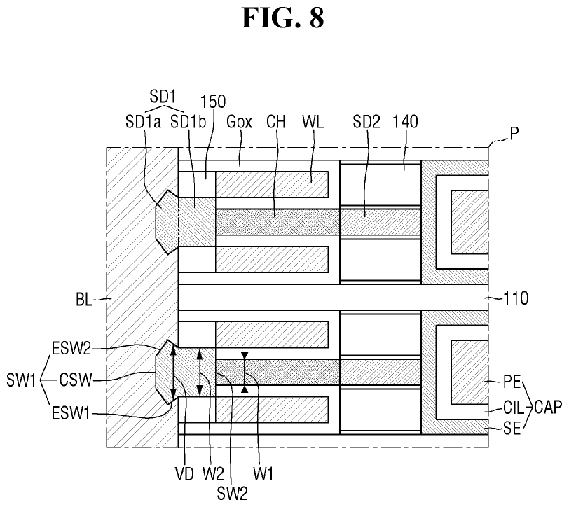

The semiconductor memory device according to some implementations will be described below with reference to FIGS. 8 to 13.

FIGS. 8 to 13 are example diagrams of the semiconductor memory device. For convenience of explanation, repeated contents of those explained using FIGS. 2 to 7 will be briefly explained or omitted.

First, referring to FIG. 8, the first side wall SW1 of the first source/drain region SD1 further includes a connecting part CSW.

The connecting part CSW of the first side wall SW1 of the first source/drain region SD1 may be disposed between the first extending part ESW1 and the second extending part ESW2 to connect the first extending part ESW1 and the second extending part ESW2 to each other. For example, one side of the connecting part CSW may be connected to the first extending part ESW1, and the other side of the connecting part CSW may be connected to the second extending part ESW2.

In some implementations, the connecting part CSW may extend in the third direction D3. The connecting part CSW may extend in a direction perpendicular to the upper side of the substrate 100. That is, the first side wall SW1 may include a tip part at a portion in which the connecting part CSW and the first extending part ESW1 are in contact with each other. Similarly, the first side wall SW1 may include a tip part at a portion in which the connecting part CSW and the second extending part ESW2 are in contact with each other. However, the technical idea of the present disclosure is not limited thereto.

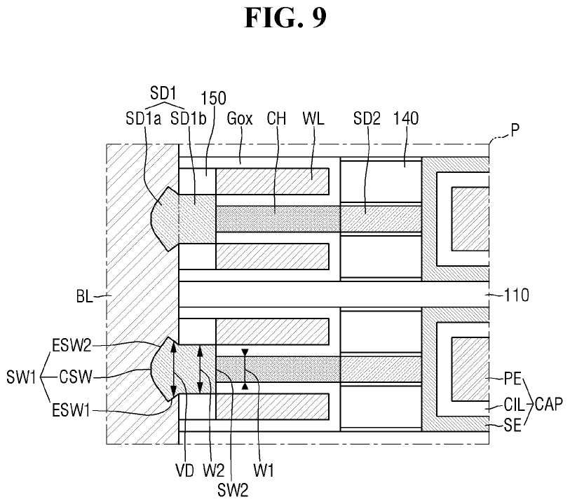

Referring to FIG. 9, the first side wall SW1 of the first source/drain region SD1 further includes a connecting part CSW.

The connecting part CSW of the first side wall SW1 of the first source/drain region SD1 may connect the first extending part ESW1 and the second extending part ESW2. For example, one side of the connecting part CSW may be connected to the first extending part ESW1, and the other side of the connecting part CSW may be connected to the second extending part ESW2.

In some implementations, the connecting part CSW may be a curved face. The connecting part CSW may be concave with respect to the channel region CH. That is, a distance in a horizontal direction from the channel region CH to the connecting part CSW may gradually increase and then decrease from the first extending part ESW1 to the second extending part ESW2. Here, the horizontal direction may be a direction parallel to the upper side of the substrate 100.

In some implementations, the first side wall SW1 may not include a tip part at the portion in which the connecting part CSW and the first extending part ESW1 are in contact with each other. Similarly, the first side wall SW1 may not include a tip part at the portion in which the connecting portion CSW and the second extending part ESW2 are in contact with each other.

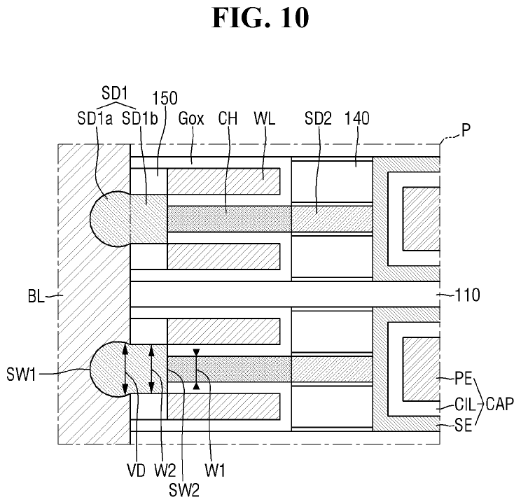

Referring to FIG. 10, the first side wall SW1 of the first source/drain region SD1 is a curved face. The first side wall SW1 of the first source/drain region SD1 is concave with respect to the channel region CH. The first side wall SW1 of the first source/drain region SD1 does not include a tip part. Also at this time, the width VD of the first region SD1a of the first source/drain region SD1 in the third direction D3 gradually increases and then decreases, as it goes away from the channel region CH.

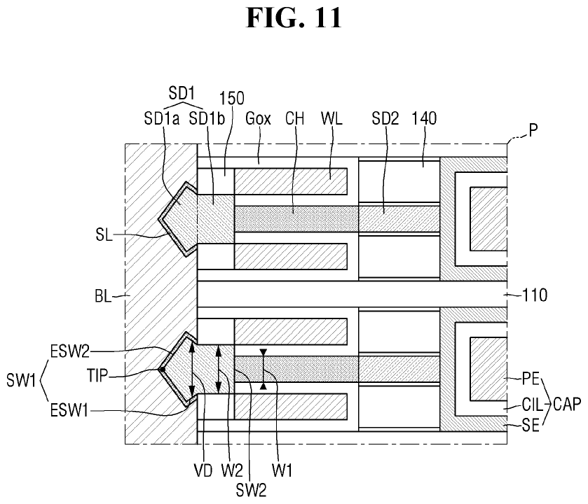

Referring to FIG. 11, the semiconductor memory device further includes a silicide film SL.

The silicide film SL may be interposed at the boundary between the bit line BL and the first source/drain region SD1. The silicide film SL may be provided on the first side wall SW1 of the first source/drain region SD1. The silicide film SL may be conformally formed on the first side wall SW1 of the first source/drain region SD1. The silicide film SL may include, for example, a metal silicide material.

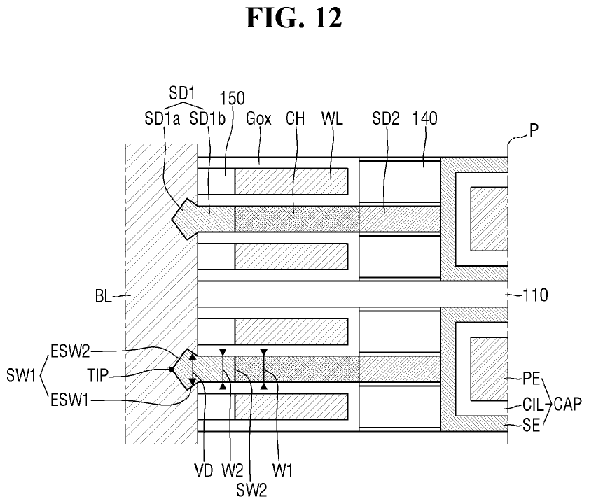

Referring to FIG. 12, a part of the second region SD1b of the first source/drain region SD1 is in contact with the gate insulating film Gox. The second region SD1b of the first source/drain region SD1 is not in contact with the capping insulating film 150.

The gate insulating film Gox may not be removed in the process of forming the first source/drain region SD1. Therefore, the second region SD1b of the first source/drain region SD1 may be interposed between the gate insulating films Gox. The second region SD1b of the first source/drain region SD1 may overlap the gate insulating film Gox in the third direction D3. On the other hand, the second region SD1b of the first source/drain region SD1 may not overlap the gate insulating film Gox in the second direction D2.

In some implementations, the first width W1 and the second width W2 may be equal to each other. This may be because the gate insulating film Gox is not removed in the process of forming the first source/drain region SD1.

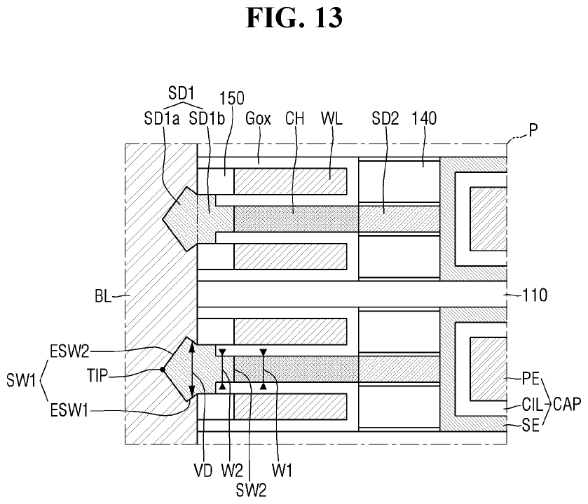

Referring to FIG. 13, the second region SD1b of the first source/drain region SD1 has a ‘T’ shape rotated counterclockwise by 90 degrees. In the process of forming the first source/drain region SD1, the gate insulating film Gox is removed to a lesser extent. Accordingly, the gate insulating film Gox protrudes from the channel region CH toward the bit line BL. Therefore, the second region SD1b of the first source/drain region SD1 has a ‘T’ shape in which the width of the portion adjacent to the first region SD1a is wider than the width of the portion adjacent to the channel region CH.

In some implementations, the first width W1 and the second width W2 may be equal to each other. However, in the second region SD1b, the width of the portion that overlaps the gate insulating film Gox in the third direction D3 is smaller than the width of the portion that does not overlap the gate insulating film Gox in the third direction D3.

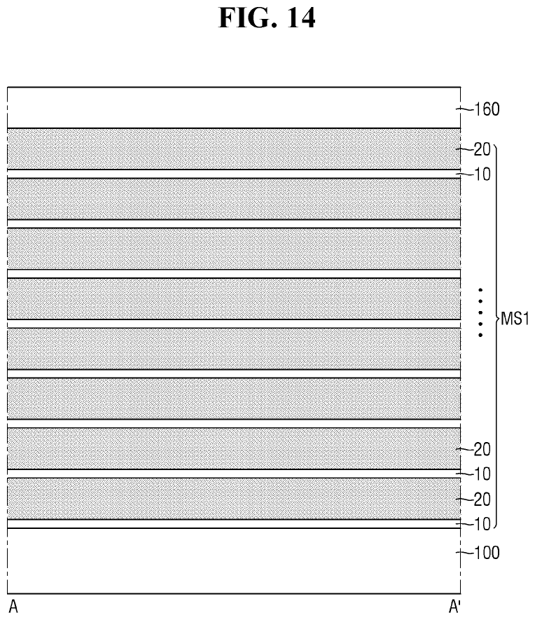

A method for fabricating a semiconductor memory device according to some implementations will be described below with reference to FIGS. 14 to 27.

FIGS. 14 to 27 are example intermediate diagrams for explaining the method for fabricating a semiconductor memory device. For reference, FIGS. 14 to 27 are diagrams showing the method for fabricating the cross-sections of FIGS. 4 and 7.

First, referring to FIG. 14, a substrate 100 is provided. A first mold structure MS1 is formed on the substrate 100.

The first mold structure MS1 may include first sacrificial films 10 and semiconductor films 20. The first mold structure MS1 may be formed by alternately stacking the first sacrificial films 10 and the semiconductor films 20. For example, the first sacrificial films 10 may be formed between the semiconductor films 20 adjacent in the third direction D3, and the semiconductor films 20 may be formed between the first sacrificial films 10 adjacent in the third direction D3. The thickness of the first sacrificial films 10 may be thinner than the thickness of the semiconductor films 20.

The first sacrificial films 10 may be formed of a material having an etching selectivity with respect to the semiconductor film 20. For example, the first sacrificial films 10 may be formed of at least one of silicon germanium, silicon oxide, silicon nitride, and silicon oxynitride. The semiconductor films 20 may be formed of, for example, silicon, germanium, silicon-germanium, or IGZO (Indium Gallium Zinc Oxide). According to some implementations, the semiconductor films 20 may be formed of the same material as the substrate 100. For example, the semiconductor film 20 may be a monocrystalline silicon film or a polycrystalline silicon film.

In some implementations, the first sacrificial films 10 and the semiconductor films 20 may be formed, using an epitaxial growth process. As an example, the semiconductor films 20 may be a monocrystalline silicon film, and the first sacrificial film 10 may be a silicon germanium film having a super lattice structure.

An upper insulating film 160 may be formed on the first mold structure MS1. The upper insulating film 160 may cover the semiconductor films 20 disposed at the highest vertical level among the semiconductor films 20. The upper insulating film 160 may be formed of an insulating material having an etching selectivity with respect to the first sacrificial films 10 and the semiconductor films 20. For example, the upper insulating film 160 may be formed of silicon oxide.

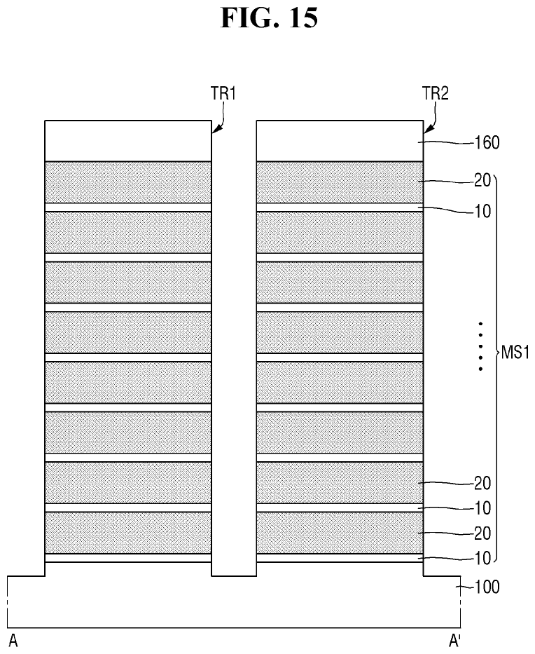

Referring to FIG. 15, a first trench TR1 and a second trench TR2 which penetrate the first mold structure MS1 are formed. The first trench TR1 and the second trench TR2 each exposes the side walls of the first sacrificial film 10 and the semiconductor films 20.

Formation of the first trench TR1 and the second trench TR2 may include forming a mask pattern having openings corresponding to the first trench TR1 and the second trench TR2 on the first mold structure MS1, and etching the first mold structure MS1 using the mask pattern as an etching mask.

The first trench TR1 and the second trench TR2 may expose the upper side of the substrate 100, and the upper side of the substrate 100 below the first trench TR1 and the second trench TR2 is recessed by over-etch during etching to form a recess region.

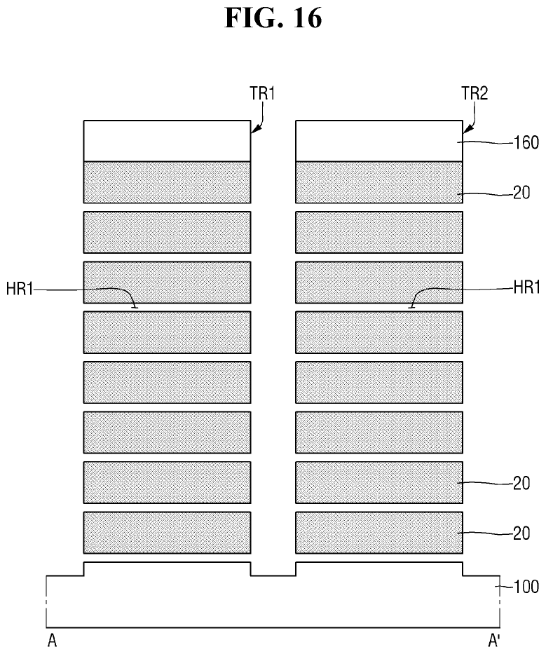

Referring to FIG. 16, the first sacrificial films 10 exposed by the first trench TR1 and the second trench TR2 are removed.

First horizontal regions HR1 may be formed between the semiconductor films 20 adjacent in a vertical direction (the third direction D3). Formation of the first horizontal region HR1 may include performing an etching process having an etching selectivity with respect to the substrate 100 and the semiconductor films 20 to isotropically etch the first sacrificial film 10. When removing the first sacrificial films 10, the semiconductor films 20 may be spaced apart from each other in the third direction D3 without collapsing.

The thickness of the first horizontal regions HR1 in the third direction D3 may be substantially the same as the thickness of the first sacrificial films 10. A distance in the third direction D3 between the semiconductor films 20 adjacent to each other may be substantially the same as the thickness of the first sacrificial film 10.

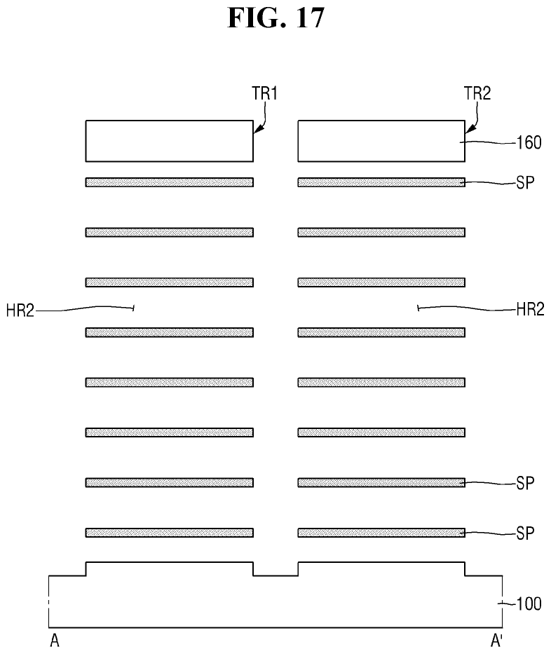

Referring to FIG. 17, an enlargement process for increasing the thickness of the first horizontal regions HR1 in the third direction D3 is performed. As an example, the enlargement process includes etching the upper and lower sides of the semiconductor film 20 exposed by the first horizontal regions HR1. The enlargement process includes performing an isotropic etching process having an etching selectivity with respect to the upper insulating film 160. The thickness of each of the semiconductor films 20 is reduced by the enlargement process. Accordingly, the semiconductor patterns SP is formed, and the second horizontal regions HR2 each is formed between the semiconductor patterns SP adjacent to each other in the third direction D3.

In some implementations, an oxidation process may be performed on the semiconductor pattern SP, and sacrificial oxide films may be formed on the surface of the semiconductor pattern SP, accordingly. After that, the sacrificial oxide films may be removed, and the surface of the semiconductor pattern SP may be exposed again. After removing the sacrificial oxide film, the distance between the semiconductor patterns SP adjacent to each other in the third direction D3 may be increased. That is, the second horizontal regions HR2 may be further enlarged in the vertical direction.

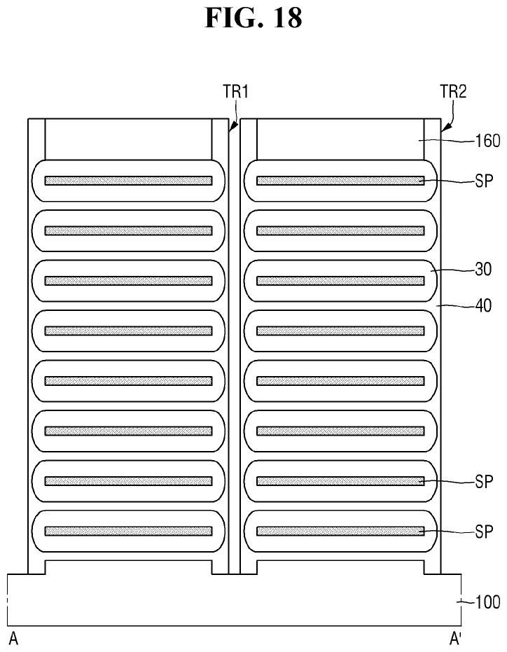

Referring to FIG. 18, a second sacrificial film 30 and a pre-interlayer insulating film 40 are formed on the surface of the semiconductor pattern SP. The second sacrificial film 30 and the pre-interlayer insulating film 40 are sequentially deposited.

The second sacrificial film 30 may include a material having an etching selectivity with respect to the substrate 100 and the semiconductor pattern SP. For example, the second sacrificial film 30 may be formed of at least one of silicon oxide, silicon nitride, and silicon oxynitride. The second sacrificial film 30 may be formed by an atomic layer deposition method (ALD) or a chemical vapor deposition method (CHD).

The second sacrificial film 30 may be deposited to surround each of the semiconductor patterns SP. The second sacrificial film 30 may be deposited to a thickness smaller than half the thickness of each of the second horizontal regions HR2 in the third direction D3. Accordingly, after depositing the second sacrificial film 30, a gap region may be defined between the semiconductor patterns SP adjacent to each other in the third direction D3.

Subsequently, a pre-interlayer insulating film 40 may be formed on the second sacrificial film 30 to fill the second horizontal regions HR2 in which the second sacrificial film 30 is formed. The pre-interlayer insulating film 40 may be formed of an insulating material having an etching selectivity with respect to the second sacrificial film 30 and the substrate 100. As an example, the pre-interlayer insulating film 40 may be formed of silicon oxide.

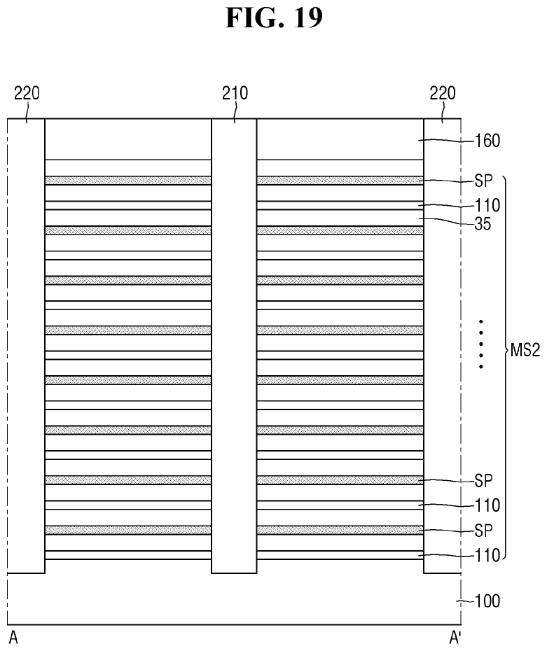

Referring to FIG. 19, the pre-interlayer insulating film 40 and the second sacrificial film 30 are etched to form a second mold structure MS2. The second mold structure MS2 includes a plurality of interlayer insulating films 110, a plurality of semiconductor patterns SP, and a plurality of second sacrificial patterns 35.

Specifically, the interlayer insulating film 110 may be formed by partially etching the pre-interlayer insulating film 40. The interlayer insulating film 110 may be formed by isotropically etching the pre-interlayer insulating film 40 until the second sacrificial film 30 is exposed to the first and second trenches TR1 and TR2. The interlayer insulating films 110 may be separated from each other in the third direction D3.

After the interlayer insulating film 110 is formed, a part of the second sacrificial film 30 may be etched to form second sacrificial patterns 35. The second sacrificial pattern 35 may be formed by isotropically etching the second sacrificial film 30 until the semiconductor pattern SP is exposed. The second sacrificial patterns 35 may be separated from each other in the third direction D3. The semiconductor patterns SP may each be disposed between the second sacrificial patterns 35.

After forming the second mold structure MS2, first and second buried insulating patterns 210 and 220 that fill the first and second trenches TR1 and TR2 may be formed. Formation of the first and second buried insulating patterns 210 and 220 may include forming a buried insulating film for filling the first and second trenches TR1 and TR2, and planarizing the buried insulating film to expose the upper side of the upper insulating film 160. The first and second buried insulating patterns 210 and 220 may each be formed of, for example, at least one of silicon oxide, silicon nitride, and silicon oxynitride. Each of the first and second buried insulating patterns 210 and 220 may be formed of a single film or multiple films.

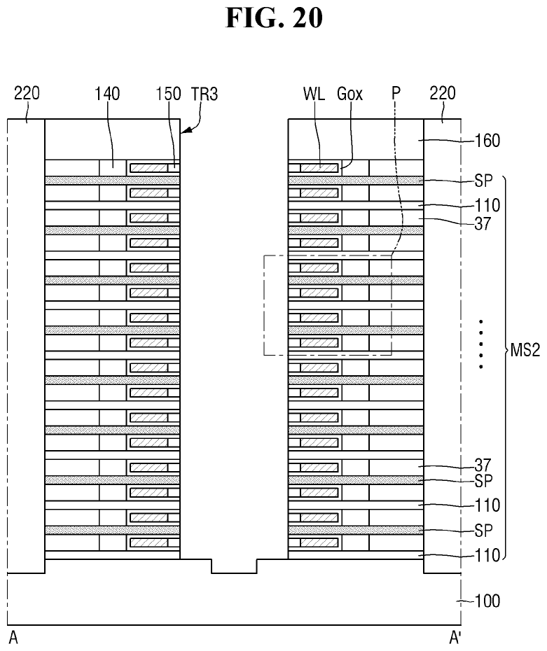

Referring to FIGS. 20 and 21, the first buried insulating pattern 210 and a part of the second mold structure are etched to form a third trench TR3. The width of the third trench TR3 is greater than the width of the first buried insulating pattern 210.

A part of the second sacrificial patterns 35 exposed by the third trench TR3 may then be removed. The second sacrificial patterns 35 may be removed through an isotropic etching process. Since the second sacrificial patterns 35 have an etching selectivity with respect to the interlayer insulating film 110 and the semiconductor patterns SP, the interlayer insulating film 110 and the semiconductor patterns SP are not removed, and the second sacrificial patterns 35 may be selectively removed.

As an example, when the second sacrificial patterns 35 are a silicon nitride film and the interlayer insulating film 110 is a silicon oxide film, the second sacrificial patterns 35 may be etched, using an etchant including phosphoric acid. Third sacrificial patterns 37 may be formed by removing a part of the second sacrificial patterns 35.

A spacer insulating film 140 may be formed in the space from which the second sacrificial patterns 35 are removed. The spacer insulating film 140 may fill a part of the space from which the second sacrificial pattern 35 is removed. Subsequently, the gate insulating film Gox, the word line WL, and the capping insulating film 150 may be formed in the space that is left over after the spacer insulating film 140 is filled.

First, the gate insulating film Gox may be formed along the profile of the space which is left over after the spacer insulating film 140 is filled. The word line WL and the capping insulating film 150 may be sequentially formed on the gate insulating film Gox.

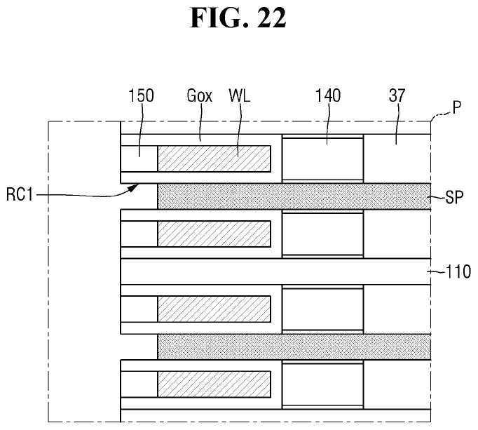

Referring to FIG. 22, a part of the semiconductor patterns SP is etched to form a first recess RC1. The semiconductor patterns SP are isotropically etched, using an etchant having an etching selectivity with respect to the gate insulating film Gox and the capping insulating film 150. Therefore, only the semiconductor patterns SP are selectively removed. A depth of the first recess RC1 is substantially the same as the thickness of the capping insulating film 150 in the second direction D2, but the technical idea of the present disclosure is not limited thereto.

At this time, if fluorine (F), chlorine (Cl) or bromine (Br) is contained in the etchant, fluorine (F), chlorine (Cl) or bromine (Br) may be detected on the exposed surfaces of the semiconductor patterns SP. Further, oxygen O may be detected on the exposed surfaces of the semiconductor patterns SP.

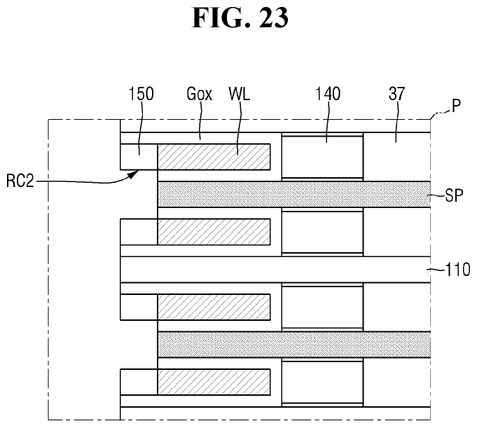

Referring to FIG. 23, a part of the gate insulating film Gox is removed to form a second recess RC2. The second recess RC2 exposes the surface of the capping insulating film 150. At this time, the second recess RC2 does not expose the word line WL.

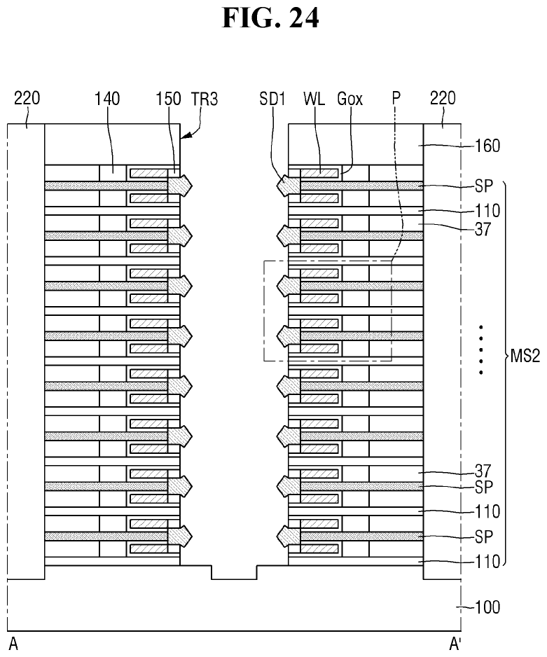

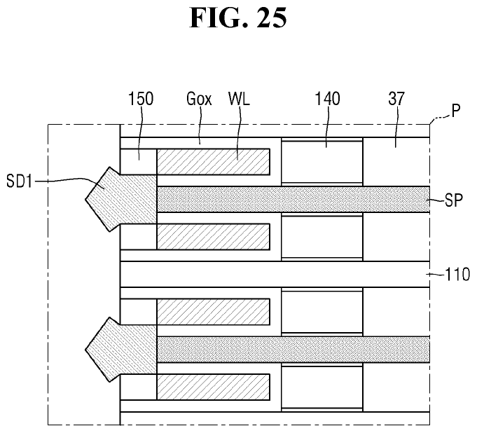

Referring to FIGS. 24 and 25, the first source/drain region SD1 is formed. The first source/drain region SD1 is formed, using a SEG (selective epitaxial growth) process. The first source/drain region SD1 fills the inside of the second recess RC2, and protrude from the side walls of the capping insulating film 150. The first source/drain region SD1 is formed, by using the semiconductor pattern SP as a seed film. The first source/drain region SD1 includes at least one of SiP and SiAs.

In some implementations, the first recess RC1 and the second recess RC2 may be formed first to expose the surfaces of the semiconductor patterns SP. Therefore, oxygen may be included in the exposed surfaces of the semiconductor patterns SP and the boundary between the surfaces of the semiconductor patterns SP and the first source/drain region SD1 (O). In addition, when an etchant containing fluorine (F), chlorine (Cl) or bromine (Br) is used in the process of forming the first recess RC1, fluorine (F), chlorine (Cl) or bromine (Br) may be included in the boundary between the surfaces of the semiconductor patterns SP and the first source/drain region SD1.

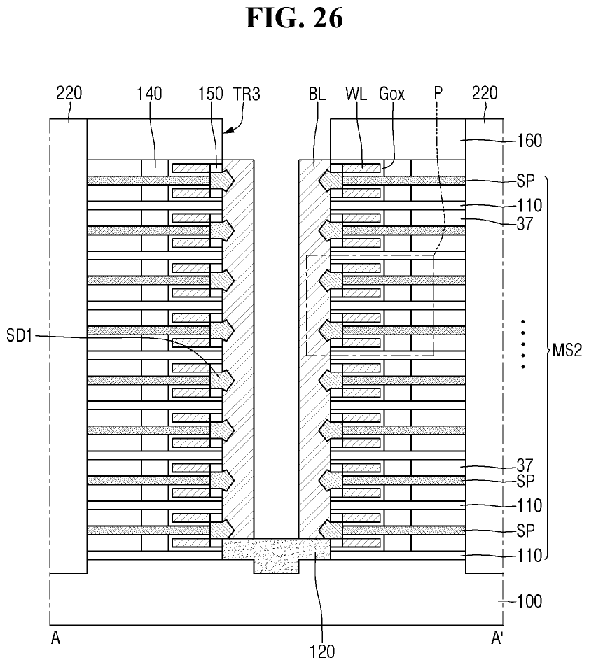

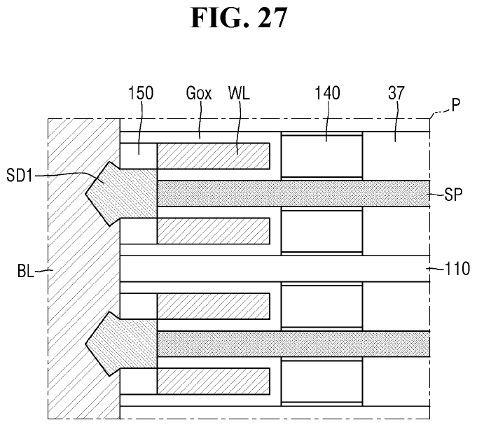

Referring to FIGS. 26 and 27, bit lines BL that cover the first source/drain region SD1, the capping insulating films 150, and the interlayer insulating film 110 are formed.

Formation of the bit lines BL may include formation of a conductive film for filling the inside of the third trench TR3 and removal of a part of the conductive film. The bit lines BL may cover the first source/drain region SD1. Since the first source/drain region SD1 protrudes from the capping insulating film 150, an area of the portion in which bit lines BL and the first source/drain region SD1 are in contact with each other may increase. Accordingly, a semiconductor memory device having improved reliability can be fabricated.

Next, referring to FIG. 4, a part of the semiconductor pattern SP may be doped to form a second source/drain region SD2. The third sacrificial patterns 37 may then be removed to form the data storage elements CAP.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a claimed combination can in some cases be excised from the combination, and the claimed combination may be directed to a subcombination or variation of a subcombination.

In concluding the detailed description, those skilled in the art will appreciate that many variations and modifications may be made to the implementations without substantially departing from the principles of the present disclosure. Therefore, the disclosed implementations of the disclosure are used in a generic and descriptive sense only and not for purposes of limitation.

What is claimed is:

1. A semiconductor memory device comprising:
a substrate;
a structure including a plurality of word lines and a plurality of interlayer insulating films, wherein the plurality of word lines and the plurality of interlayer insulating films are alternately stacked on the substrate;
a channel region disposed between two adjacent word lines of the plurality of word lines in a vertical direction;
a first source/drain region disposed on a first side of the channel region;
a second source/drain region disposed on a second side of the channel region;
a bit line which extends in the vertical direction on the substrate, wherein the bit line is connected to the first source/drain region;
a capping insulating film disposed between the bit line and the plurality of word lines; and
a data storage connected to the second source/drain region,
wherein at least a part of the first source/drain region protrudes from a sidewall of the capping insulating film toward the bit line.

2. The semiconductor memory device of claim 1, wherein at a boundary between the first source/drain region and the channel region, the channel region has a first width and the first source/drain region has a second width in the vertical direction, and wherein the first width is smaller than the second width.

3. The semiconductor memory device of claim 1, wherein the first source/drain region includes SiP or SiAs.

4. The semiconductor memory device of claim 1, wherein the first source/drain region includes a first region disposed in the bit line and a second region between the first region and the channel region, and
wherein a width of the first region in the vertical direction increases and then decreases in a direction away from the channel region.

5. The semiconductor memory device of claim 1, wherein a sidewall of the first source/drain region adjacent to the bit line includes a tip part.

6. The semiconductor memory device of claim 1, wherein a sidewall of the first source/drain region adjacent to the bit line includes a first extending part, a second extending part opposite to the first extending part, and a connecting part that connects the first extending part and the second extending part.

7. The semiconductor memory device of claim 6, wherein the connecting part extends in the vertical direction.

8. The semiconductor memory device of claim 6, wherein the connecting part is concave with respect to the channel region.

9. The semiconductor memory device of claim 1, wherein at least a part of the first source/drain region is in contact with the capping insulating film.

10. The semiconductor memory device of claim 1, wherein at a boundary between the first source/drain region and the channel region, the first source/drain region or the channel region includes oxygen (O), fluorine (F), chlorine (CI), or bromine (Br).

11. The semiconductor memory device of claim 1, comprising:
a silicide film disposed between the first source/drain region and the bit line.

12. The semiconductor memory device of claim 1, comprising:
a gate insulating film disposed between the plurality of word lines and the channel region,
wherein at least a part of the gate insulating film overlaps the first source/drain region in a horizontal direction intersecting the vertical direction.

13. A semiconductor memory device comprising:
a substrate;
a structure including a plurality of word lines and a plurality of interlayer insulating films, wherein the plurality of word lines and the plurality of interlayer insulating films are alternately stacked on the substrate;
a channel region disposed between two adjacent word lines of the plurality of word lines in a vertical direction;
a bit line which extends in the vertical direction on the substrate;
a plurality of capping insulating films disposed between the bit line and the plurality of word lines;
a first source/drain region which is disposed between the bit line and the channel region and between two adjacent capping insulating films of the plurality of capping insulating films in the vertical direction, wherein the first source/drain region at least partially overlaps the bit line in the vertical direction;
a second source/drain region opposite to the first source/drain region, wherein the channel region is disposed between the first source/drain region and the second source/drain region; and
a data storage connected to the second source/drain region,
wherein the first source/drain region includes a first region overlapping the bit line in the vertical direction and a second region between the first region and the channel region, and
wherein a width of the first region in the vertical direction increases and then decreases in a direction away from the channel region.

14. The semiconductor memory device of claim 13, comprising:
a silicide film disposed between the first source/drain region and the bit line.

15. The semiconductor memory device of claim 13, wherein at a boundary between the first source/drain region and the channel region, the channel region has a first width and the first source/drain region has a second width in the vertical direction, and wherein the first width is less than the second width.

16. The semiconductor memory device of claim 13, wherein the data storage includes a storage electrode connected to the second source/drain region, a plate electrode on the storage electrode, and a capacitor dielectric film between the storage electrode and the plate electrode.

17. The semiconductor memory device of claim 13, wherein at least a part of the first source/drain region is in contact with the plurality of capping insulating films.

18. The semiconductor memory device of claim 13, wherein at a boundary between the first source/drain region and the channel region, the first source/drain region or the channel region includes oxygen (O), fluorine (F), chlorine (Cl), or bromine (Br).

19. The semiconductor memory device of claim 13, wherein a structure of a crystal grain of the first source/drain region is different from a structure of a crystal grain of the channel region.

20. A semiconductor memory device comprising:
a substrate;
a structure including a plurality of word lines and a plurality of interlayer insulating films, wherein the plurality of word lines and the plurality of interlayer insulating films are alternately stacked on the substrate;
a channel region disposed between two adjacent word lines of the plurality of word lines in a vertical direction;
a first source/drain region disposed on a first side of the channel region;
a second source/drain region disposed on a second side of the channel region;
a bit line which extends in the vertical direction on the substrate, wherein the bit line is connected to the first source/drain region;
a silicide film disposed between the first source/drain region and the bit line;
a plurality of capping insulating films disposed between the bit line and the plurality of word lines; and
a data storage connected to the second source/drain region,
wherein the data storage includes a storage electrode connected to the second source/drain region, a plate electrode on the storage electrode, and a capacitor dielectric film between the storage electrode and the plate electrode,
wherein the first source/drain region includes a first region and a second region, wherein the first region protrudes from a plurality of sidewalls of the plurality of capping insulating films and overlaps the bit line in the vertical direction, and the second region is between the first region and the channel region,
wherein a sidewall of the first source/drain region include a first extending part and a second extending part opposite to the first extending part,
wherein a distance in the vertical direction from the first extending part to the second extending part increases and then decreases in a direction away from the channel region, and
wherein at a boundary between the first source/drain region and the channel region, the first source/drain region or the channel region includes oxygen (O), fluorine (F), chlorine (Cl), or bromine (Br).
